(19) United States
(12) Patent Application Publication
(10) Pub. No.: US 2006/0018410 A1
(43) Pub. Date: Jan. 26, 2006

(54) Multimode detection

(76) Inventors: Eko N. Onggosanusi, Allen, TX (US); Anand G. Dabak, Plano, TX (US); Srinath Hosur, Plano, TX (US)

Correspondence Address: TEXAS INSTRUMENTS INCORPORATED, P O BOX 655474, M/S 3999, DALLAS, TX, 75265, US

(21) Appl. No.: 10/899,615

(22) Filed: Jul. 26, 2004

(51) Int. Cl. H03D 1/00

(52) U.S. Cl. 375/340

(57) ABSTRACT

In a wireless MIMO system, a multimode detector selects detection mode by channel estimation: ill-conditioned channels trigger use of high performance detection, whereas well-behaved channels lead to low complexity detection. Detection modes typically include maximum likelihood, minimum mean squared error, zero forcing, and so forth.

### CROSS-REFERENCE TO RELATED APPLICATIONS

The following copending application discloses related subject matter and have a common assignee with the present application: application Ser. No. 10/618,970, filed Jul. 14, 2003.

### BACKGROUND OF THE INVENTION

The present invention relates to communication systems, and more particularly to multimode detectors and detection methods.

Wireless communication systems typically use band-limited channels with time-varying (unknown) distortion and may have multi-users (such as multiple clients in a wireless LAN). This leads to intersymbol interference and multi-user interference, and requires interference-resistant detectors and detection methods for interference-limited systems. Interference-limited systems include multi-antenna systems with multi-stream or space-time coding which have spatial interference, multi-tone systems, TDMA systems having frequency selective channels with long impulse responses leading to intersymbol interference, CDMA systems with multi-user interference arising from loss of orthogonality of spreading codes, high data rate CDMA which in addition to multi-user interference also has intersymbol interference.

Interference-resistant detectors commonly invoke one of three approaches to combat the interference: maximum likelihood sequence estimation, (adaptive) linear filtering, and decision-feedback detection. However, maximum likelihood sequence estimation has problems including impractically large computation complexity for systems with multiple transmit antennas because the decoding requires a search over the topological product of multiple copies of the symbol constellation. Linear filtering detection, such as linear zero-forcing (ZF) and linear minimum squared error (MMSE), has lower computational complexity (search over a single symbol constellation) but has relatively poor performance due to excessive noise enhancement. And decision-feedback (iterative) detectors, such as iterative ZF and iterative MMSE, decode the transmitted symbols successively with cancellation of previously-detected symbols in each detection; the order of detection may depend upon SINR or other measures of symbol reliability. Such methods have moderate computational complexity but only moderate performance.

However, these methods have problems including trade-offs of performance and complexity which are inappropriate for many conditions.

### SUMMARY OF THE INVENTION

The present invention provides multimode detectors and detection methods for adapting detection method to conditions. Preferred embodiments apply to multiple-input multiple-output (MIMO) systems.

This has advantages including performance approaching maximum likelihood detection but with complexity comparable to that of iterative interference cancellation detection.

### BRIEF DESCRIPTION OF THE DRAWINGS

FIG. 1 is a flow diagram.

FIG. 2 is a block diagram of a preferred embodiment detector.

FIGS. 3a-3f illustrate functional blocks of detectors, receivers, and transmitters.

FIGS. 4a-4d and 5a-5d illustrate simulation results.

### DESCRIPTION OF THE PREFERRED EMBODIMENTS

1. Overview

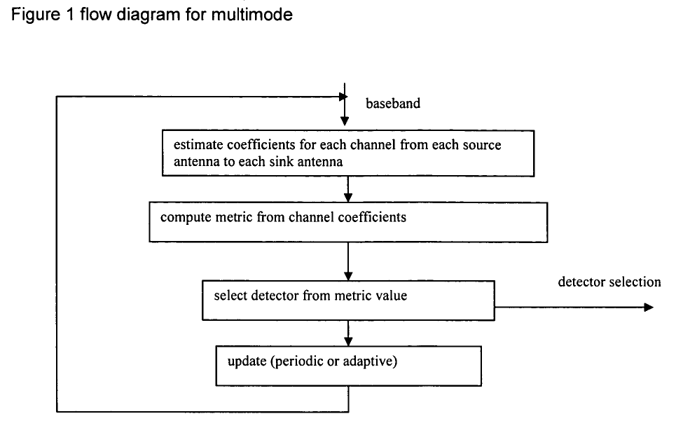

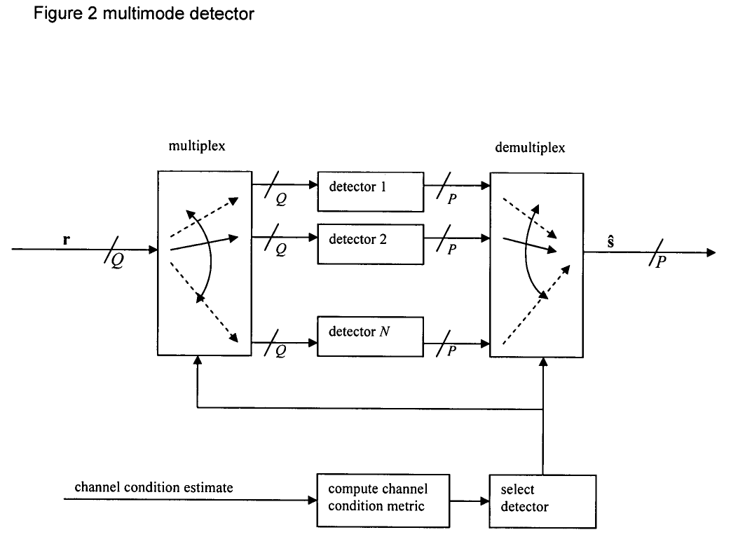

Preferred embodiment multimode detectors and detection methods have detection mode selection dependent upon channel estimation; FIG. 2 shows a preferred embodiment detector and FIG. 1 is a flow diagram of the mode selection operation which includes updating. The mode selection allows for high performance with lower effective computational complexity; indeed, a target performance (such as within 0.2 dB of maximum likelihood detection performance) could be specified and the lowest complexity (or lowest power consumption) detection meeting the performance target would be selected. Preferred embodiment receivers and transceivers include preferred embodiment detectors and/or detection methods, and apply to multi-input, multi-output (MIMO) antenna systems.

Preferred embodiment communication systems, such as cellular phones and wireless local area networks, include preferred embodiment receivers employing preferred embodiment detection. The detection computations can be performed with digital signal processors (DSPs) or general-purpose programmable processors or application specific circuitry (ASICs) or systems on a chip such as both a DSP, ASIC, and RISC processor on the same chip with the RISC processor controlling. Analog-to-digital converters and digital-to-analog converters provide coupling to the real world, and modulators and demodulators (plus antennas for air interfaces) provide coupling for transmission waveforms.

2. Interference-Limited Receivers Generally

For any interference-limited system the baseband received signal can be written in Q-dimensional vector format:
r=Hs+w
where r is the Q-vector of samples of the received baseband signal (complex numbers) corresponding to a transmission time (interval/block) n:

$$r = [ \begin{matrix}{r}_{1} ( n ) \\ {r}_{2} ( n ) \\ ⋮ \\ {r}_{Q} ( n )\end{matrix} ]$$

s is the P-vector of transmitted data symbols (sets of complex numbers of symbol constellations) for time n:

$$s = [ \begin{matrix}{s}_{1} ( n ) \\ {s}_{2} ( n ) \\ ⋮ \\ {s}_{P} ( n )\end{matrix} ]$$

H is the Q×P channel matrix of attenuations and phase shifts; and w is a Q-vector of samples of received additive (white) noise with variance per element of σ². In particular, H=[h₁ h₂ . . . h_{P}] where hₚ is the channel (maybe including multipath combining and equalization) from the pth data source to the receiver, and so:
r=Σ_{1≦p≦P}hₚsₚ+w
The channel matrix H may be estimated using known (pilot) symbols.

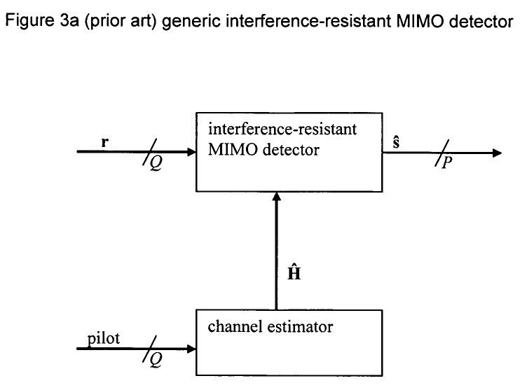

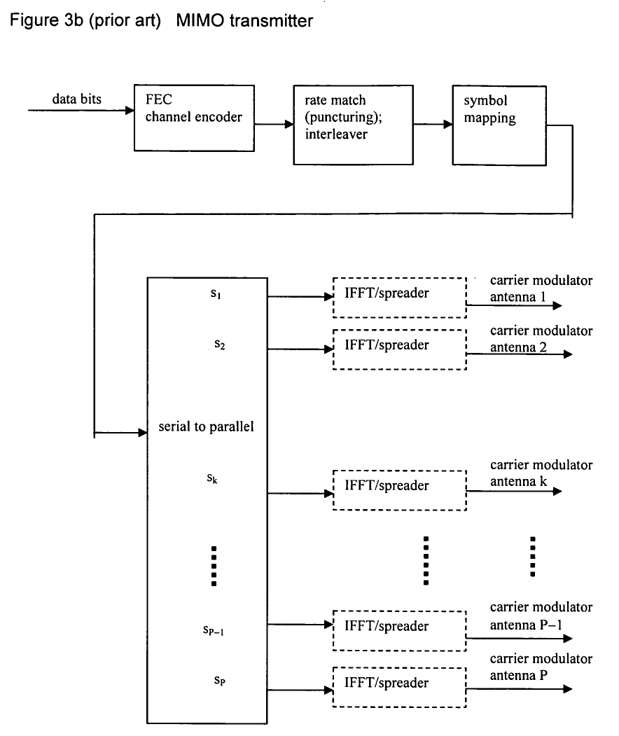

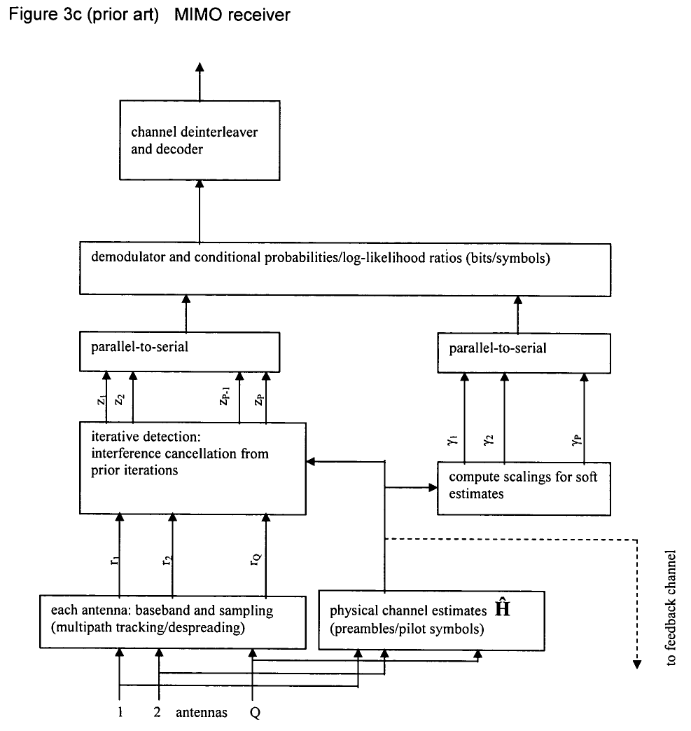

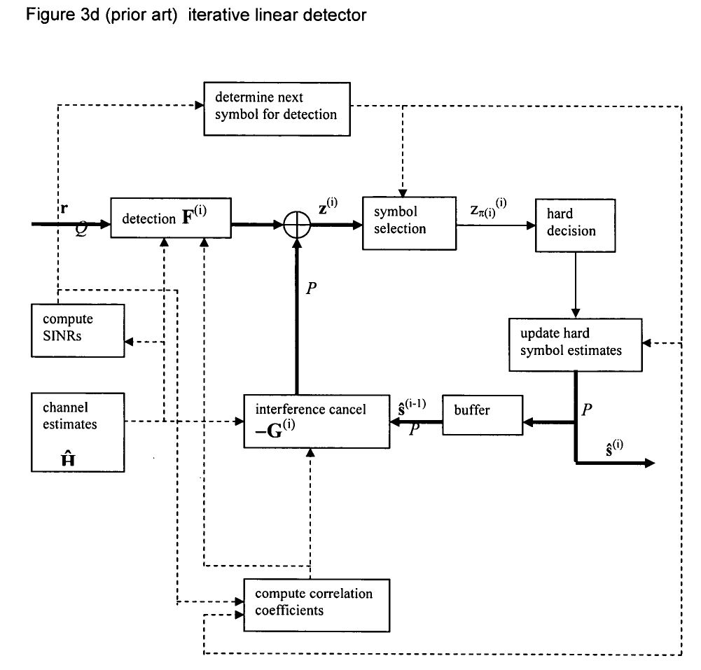

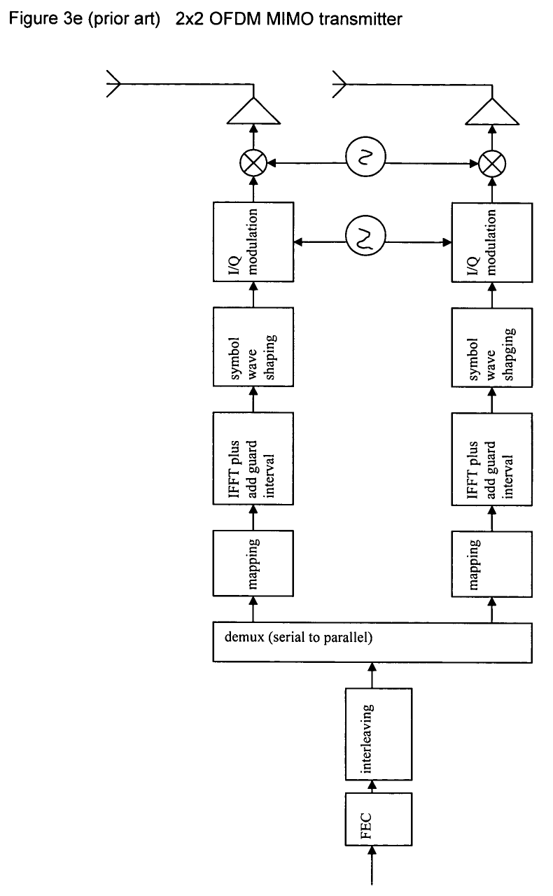

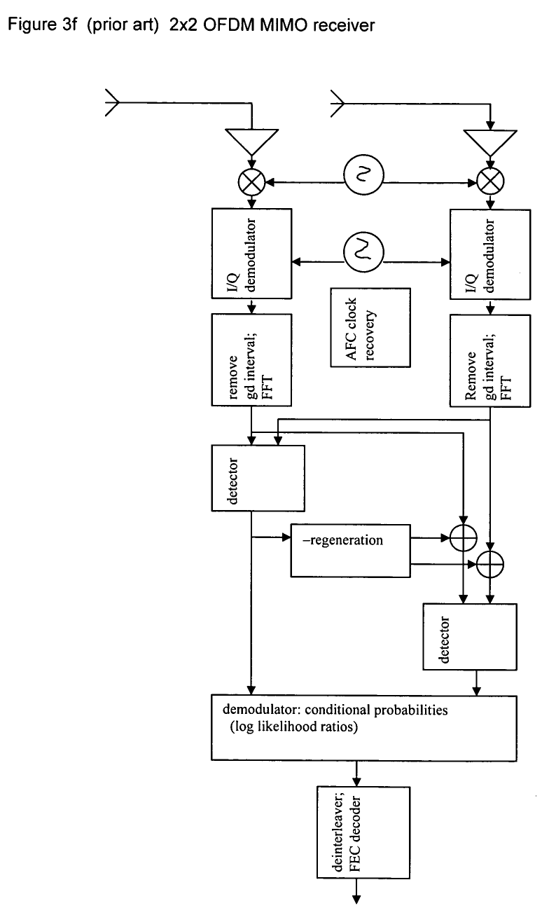

The foregoing relation applies generally to various systems with various interference problems and in which n, r, s, P, and Q have corresponding interpretations. For example:
(i) High data rate multi-antenna systems such as BLAST (Bell Labs layered space time) or MIMO and multi-stream space-time coding: spatial interference suppression techniques are used in detection; FIG. 3a shows a generic detector and FIGS. 3b-3c show a MIMO transmitter and receiver.

(ii) Broadband wireless systems employing OFDM (orthogonal frequency division multiplex) signaling and MIMO techniques for each tone or across tones; see FIGS. 3e-3f.

(iii) TDMA (time division multiple access) systems having frequency-selective channels with long impulse response which causes severe ISI (intersymbol interference). Use equalizers to mitigate ISI.

(iv) CDMA (code division multiple access) systems having frequency-selective channels which cause MUI (multi-user interference) as a result of the loss of orthogonality between spreading codes. For high data rate CDMA systems such as HSDPA and 1×EV-DV, this problem is more severe due to the presence of ISI. Equalizers and/or interference cancellation may be used to mitigate these impairments; FIG. 3d illustrates an iterative detector.

(v) Combinations of foregoing.

P is essentially the number of symbols that are jointly detected as they interfere with one another, and Q is simply the number of collected (spatial and/or temporal) samples at the receiver. Presume that different symbols that are transmitted via P different antennas are uncorrelated and may utilize different modulation schemes; thus with λₖ denoting kth symbol expected energy E[|sₖ|²]:

$$W [ {ss}^{H} ] = Λ = [ \begin{matrix}{λ}_{1} & 0 & ⋯ & 0 \\ 0 & {λ}_{2} & ⋯ & 0 \\ ⋮ & ⋮ & ⋰ & ⋮ \\ 0 & 0 & ⋯ & {λ}_{P}\end{matrix} ]$$

where ^{H} denotes Hermitian conjugate. Because there are P independent sources, Q must be at least as large as P to separate the P symbols. A detector in a receiver as in FIG. 3c outputs soft estimates z of the transmitted symbols s to a demodulator and decoder.

For linear filtering equalization detectors, such as linear zero-forcing (LZF) or linear minimum mean square error (LMMSE), the soft estimates, denoted by P-vector z, derive from the received signal by linear filtering with P×Q filter matrix F; namely, z=F r.

LZF detection essentially takes F to be the pseudoinverse of H; namely,
F_{LZF}=[H^{H}H]⁻¹H^{H}
For an invertible matrix H, F reduces to the inverse, H⁻¹.

In contrast, LMMSE detection finds the filter matrix F by minimizing the mean squared error, E[∥z−s∥²]. With perfect estimation of the channel H, the minimizing matrix F is given by:

$$\begin{matrix}{F}_{LMMSE} = {[ {H}^{H} H + {σ}^{2} {Λ}^{- 1} ]}^{- 1} {H}^{H} \\ = Λ {{H}^{H} [ H Λ {H}^{H} + {σ}^{2} {I}_{Q} ]}^{- 1}\end{matrix}$$

where I_{Q} is the Q×Q identity matrix. Note that F has the form of a product of an equalization matrix with the matched filter matrix, H^{H}, for the channel. Also, note that this LMMSE detector is biased; however, a normalization can correct this bias as indicated in FIG. 3c.

Essentially, LZF detection nulls out the interference at the expense of excessive noise enhancement, while LMMSE detection minimizes the sum of interference and noise energy to provide a balanced trade-off between bias (due to residual interference) and variance (due to noise enhancement). But then each component of z is processed separately to obtain a corresponding hard symbol estimate. That is, a hard estimate, ŝᵢ, for the ith symbol, sᵢ, comes from application of a hard decision operator to the soft estimate: ŝᵢ=D{xᵢ} for i=1, 2, . . . , P, where D{ } is a non-linear decision device, usually a single-input, single-output (SISO) maximum-likelihood (ML) detector.

A typical iterative (decision-feedback) detector (IZF or IMMSE) for blocks of P symbols has a series of P linear detectors (P iterations) with each linear detector followed by a (hard) decision device and interference subtraction (cancellation). Each of the P linear detectors (iterations) generates both a hard and a soft estimate for one of the P symbols. The hard estimate is used to regenerate the interference arising from the already-estimated symbols which is then subtracted from the received signal, and the difference used for the next linear symbol estimation. Hence, the hard symbol estimates, ŝᵢ, are also computed in a disjoint fashion.

On the other hand, the optimal joint maximum likelihood (ML) detector generates the hard symbol estimates as:
ŝ_{ML}=arg min_{sεC}|r−Hs|²
where C=C₁×C₂× . . . ×C_{P} is the P-dimensional constellation of P-vectors of symbols and has size Π_{1≦j≦P} |Cⱼ| where |Cⱼ| denotes the number of elements in constellation Cⱼ. Thus the hard symbol estimates are jointly computed, and the computational complexity of this optimal detection is proportional to the constellation size which is exponential in P. Alternatively, a soft-decision ML detector that generates bit/symbol probabilities (or log likelihood ratios) can be used.

When an error correcting code is employed, soft symbol or soft bit log likelihood ratio (LLR) estimates are often required for soft decoding operations. While soft symbol estimates can be obtained in many ways, the conditional expectation estimator is optimal. The conditional expectation estimator is:

$$\hat{s} = E [ s \vert r ] = \frac{{\sum }_{s ∈ C}^{} s \times exp ( - {‖ r - Hs ‖}^{2} / {σ}^{2} )}{{\sum }_{s ∈ C}^{} exp ( - {‖ r - Hs ‖}^{2} / {σ}^{2} )}$$

The performance loss of iterative detectors comes from the disjoint processing of the soft symbol estimates, zᵢ, to obtain the corresponding hard symbol estimates, ŝᵢ. For linear and iterative detectors, bit LLRs associated with different symbols from different transmit antennas are computed disjointly. For the optimal joint ML detector, however, bit LLRs associated with different symbols from different transmit antennas are jointly computed. The fundamental operations for each detector are identical regardless whether a forward error correcting code is used or not.

3. Preferred Embodiment Multimode Detectors

The performance difference between two MIMO detectors depends upon the channel conditions. In general, detectors with higher complexity outperform detectors with lower complexity. As an example, the following detectors are ranked according to their performance and complexity:
1. joint ML detector: best performance, highest complexity
2. iterative detectors (IZF/IMMSE)
3. linear detectors (LZF/LMMSE)
4. maximum ratio combining (MRC) detector: worst performance (not interference resistant in general), lowest complexity
   Different variations of the above detectors are also possible, such as the decision feedback reduced state ML detector described in cross-referenced copending application Ser. No. 10/618,970.

When the channels associated with different transmit antennas are orthogonal (i.e., [symbol] hⱼ|hₖ [symbol] =0 for j≠k where [symbol] | [symbol] denotes the inner (scalar) product), all of the preceding detectors have the same performance. In fact, they are mathematically equivalent due to the absence of interference. In general, {h₁, h₂, . . . h_{P}} are not orthogonal. The degree to which {h₁, h₂, . . . h_{P}} are correlated determines the performance differences among different MIMO detectors. As {h₁, h₂, . . . h_{P}} become more correlated, the performance difference between the ML detector and a linear detector becomes large. This is mainly due to the excessive noise enhancement from the linear detector as linear detectors attempt to invert the correlation effect among different channels associated with different transmit antennas. While iterative detectors result in significantly reduced noise enhancement compared to linear detectors, iterative detectors still fall short in performance compared to the optimal ML detector.

FIG. 2 shows a preferred embodiment multimode detector which includes N MIMO detectors having different performance and complexity, where the performance and complexity are inversely related. For a given channel estimation, H, the preferred embodiment detector computes a channel metric f(H), and based on f(H) selects one of the N detectors by setting the multiplexer and demultiplexer. A first preferred embodiment selects detectors as follows:
(i) when f(H) indicates that the channel is “well-behaved” in the sense of low correlations among the {h₁, h₂, . . . h_{P}}, then a low complexity detector is selected; this saves computations and thus energy in battery-operated devices.
(ii) when f(H) indicates that the channel is “ill-conditioned” in the sense of large correlation among the {h₁, h₂, . . . h_{P}}, then a high complexity detector is selected; this higher performance overcomes channel condition problems.
   Generally, f(H) is a function of the Q×P matrix H and may have scalar, vector, or matrix values. In any case, the image space of f(H) is partitioned into N regions with each region corresponding to one of the N detectors, and the selector sets the multiplexer-demultiplexer according to the value of f(H).

The N detectors could be hardwired or stored programs (e.g., ROM) and run on a programmable processor or a combination of such. Also, the channel estimation and metric computation can be updated, either periodically or adaptively such as in response to detection error correction rates. And the detector selection using the metric value may include hysteresis when switching from one detector to another detector.

The advantages of the preferred embodiment include the use of high complexity detectors only when the channel is sufficiently ill-conditioned to require them. This results in a reduction of average computational complexity which translates to (battery-operated) receiver power savings while maintaining overall receiver performance. And the tradeoff between performance and complexity can be adjusted by redefinition of the partitioning of the f(H) image space.

Two examples of practical f(H)s follow; one uses a condition number for the channel, and the other relies upon the distribution of the channel correlations. In particular, given a channel estimate H, the first example computes H^{H}H and finds the eigenvalues of H^{H}H; then the ratio of largest eigenvalue to smallest eigenvalue defines the condition number, CN(H^{H}H). Note that H^{H}H is always Hermitian, so the eigenvalues are real. Now a large value of f(H)=CN(H^{H}H) indicates the smallest eigenvalue is close to 0 and that H is close to being singular (has less than maximum rank); thus a high performance detector should be used. Indeed, for a MMSE-type detector, f(H)=CN(H^{H}H+σ²I_{P}) may be a more appropriate metric. The condition number measures eigenvalue spread but does not always reflect the correlations of the channels associated with different transmit antennas. For instance, in the case P=2 and with orthogonal channels ( [symbol] h₁|h₂ [symbol] =0), it is still possible that one channel has much greater attenuation than the other channel, so that ∥h₁∥>>∥h₂∥ and consequently a large CN(H^{H}H) value, although the orthogonal channels implies use of a low complexity detector.

For the second example, f(H) derived from the distribution of channel correlations, first define the normalized correlations for j,k=1, 2, . . . , P:
Cⱼₖ(H)=| [symbol] hⱼ|hₖ [symbol] |²/∥hⱼ∥²∥hₖ∥²
Of course, the [symbol] hⱼ|hₖ [symbol] are just the matrix elements of H^{H}H. Then the mean cross-correlation metric is defined as:
MCC(H)=Σ_{1≦j≠k≦P}Cⱼₖ(H)/P(P−1)
And the variance of cross-correlations is:
VCC(H)=Σ_{1≦j≠k≦P}(Cⱼₖ(H)−MCC(H))²/P(P−1)
Similarly, other statistical metrics can be derived from combinations of the normalized correlations. Indeed, the use of f(H)=MCC(H) treats all channel correlations roughly equally, whereas f(H)=VCC(H) emphasizes outliers from the mean, either larger or smaller. Note that different metrics may be better for different scenarios; and in this case, one may use a combination of several metrics to achieve the most desirable result. For instance, one may use a combination of both MCC(H) and VCC(H) for f(H) and detector selection.

After a metric f(H) has been chosen, the partition the image space of f(H) into N regions to define selection of the N detectors available. For example, when f(H) has real values, the partitioning of the image space amounts to selecting N−1 thresholds, γ₁, γ₂, . . . , γ_{N-1}, to define the N regions. Then with the implicit understanding γ₀=−∞ and γ_{N}=∞, when γₙ₋₁≦f(H)<γₙ, the selection is detector n.

As a simple example, consider N=2 with the joint ML and the iterative MMSE (IMMSE) detectors available. First, choose the metric f(H)=MCC(H); note that the normalization of Cⱼₖ(H) implies MCC(H) lies in the range [0,1]. Next, pick the threshold γ₁. Then the detector selection is IMMSE when MCC(H)<γ₁ and ML when γ₁≦MCC(H). The threshold parameter γ₁ is chosen to facilitate a trade-off between performance and complexity. A smaller γ₁ results in more frequent usage of the ML detector and higher performance but consequent higher power consumption. Simulation results quantify this trade-off; see the following section.

Further with the foregoing example, the alternative choice of metric f(H)=CN(H^{H}H+σ²I₂) similarly requires a threshold γ₁, but in this case the values of CN(H^{H}H+σ²I₂) lie in the range [1,∞).

4. Simulations

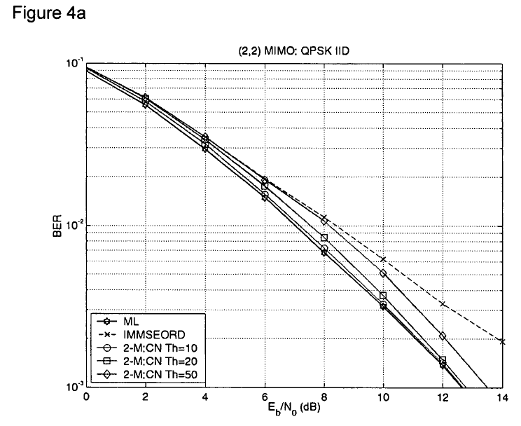

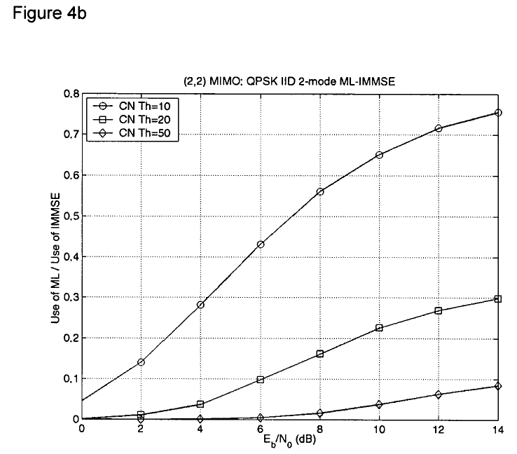

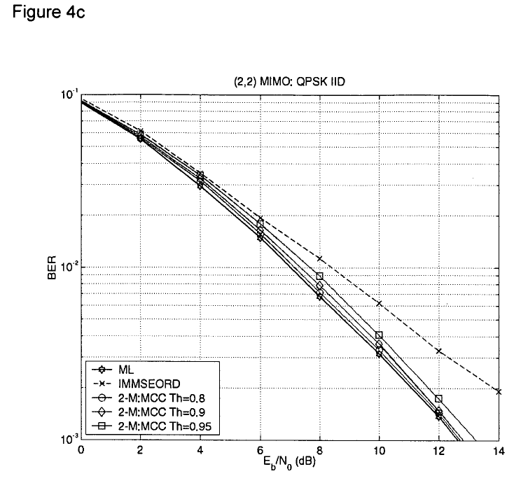

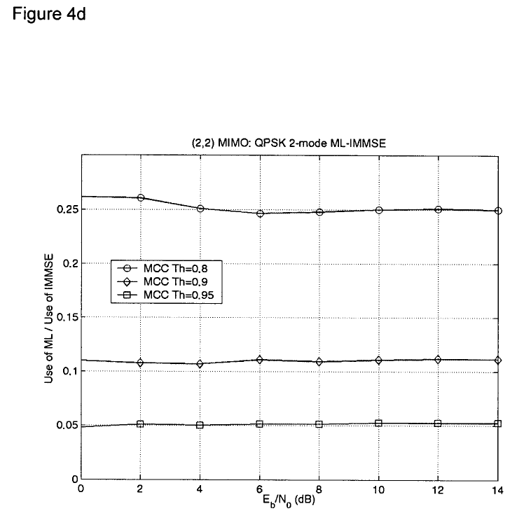

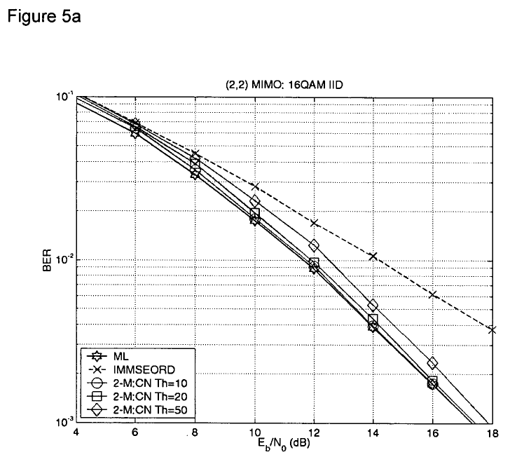

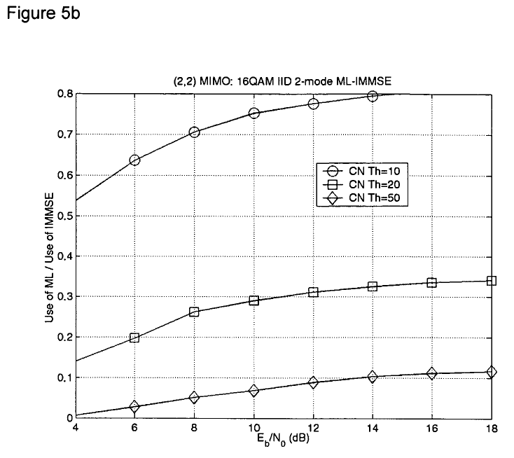

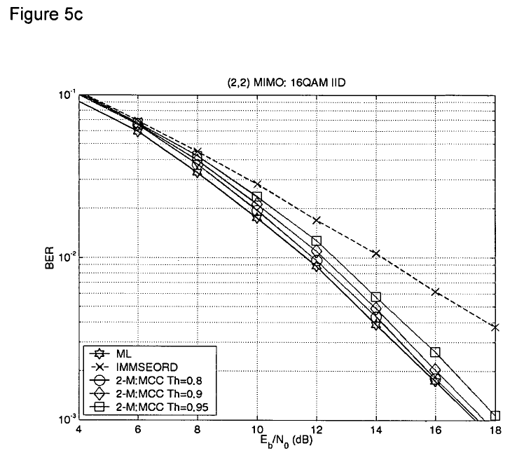

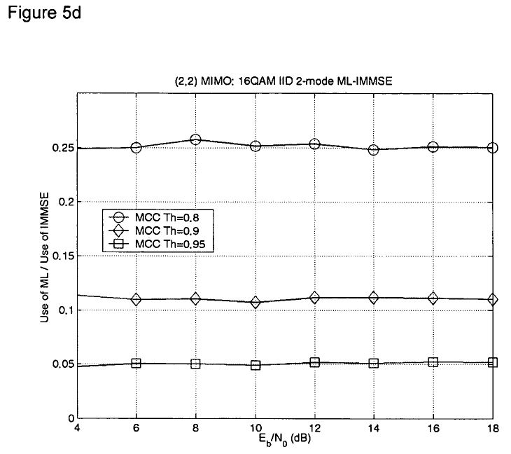

FIGS. 4a-4d and 5a-5d illustrate the performance and detector utilization of a 2-mode preferred embodiment detector (ML and IMMSE modes) with QPSK and 16 QAM modulation, respectively.

In particular, for QPSK modulation FIG. 4a illustrates the bit error rate (BER) as a function of bit energy-to-noise ratio (E_{b}/N₀) for ML detection, ordered IMMSE detection, and the preferred embodiment 2-mode (with ML and ordered IMMSE detections) using the metric f(H)=CN(H^{H}H+σ²I₂) with three different thresholds: γ₁=10, 20, and 50 (indicated by Th in the Figures). FIG. 4b shows the corresponding ratio of ML to ordered IMMSE detection used. FIG. 4c is analogous to FIG. 4a but with the metric f(H)=MCC(H) and thresholds γ₁=0.8, 0.9, and 0.95, and FIG. 4d is similarly analogous to FIG. 4b for the MCC(H) metric. Notice that the MCC(H) metric is more efficient than the CN(H^{H}H+σ²I₂) metric. Also, the complexity saving for the CN(H^{H}H+σ²I₂) metric depends upon E_{b}/N₀. With the MCC(H) metric, near-ML performance (difference less than 0.1 dB) can be obtained by using ML detection only 25% of the time (with Th=0.8); see FIG. 4d. With Th=0.9, ML detection is used only 10% of the time and with a performance loss of 0.2 dB compared to the case when ML detection is used all of the time.

FIGS. 5a-5d are analogous to FIGS. 4a-4b but for 16 QAM modulation.

5. Modifications

The preferred embodiments can be modified in various ways while retaining one or more of the features of a multimode detector with channel analysis metric selection of detection mode.

For example, the set of detectors available for selection could include any convenient types and could be updated periodically or adaptively. Also, the switching between detectors (detection modes) could be subject to hysteresis in either the sense of the metric must cross a threshold and maintain the threshold crossing for a minimal time interval prior to switching or in the sense of the metric must cross the threshold by a minimum amount prior to selection switching or a combination of both senses. For example, in the And the detection methods could have various enhancements.

Another possible variation is the use of long-term channel condition instead of short-term (instantaneous) channel. That is, the detector selection is done periodically on a long-term basis based on long-term channel condition(s) such as the second order statistics of the channel. For instance, a metric based on the following statistics can be used (analogous to the cross-correlation metric):
ACⱼₖ(H)=E[|hⱼ|hₖ [symbol] |²]/E[∥hⱼ∥²] E[∥hₖ∥²]
where E[.] denotes statistical expectation (i.e., average over a set of samples). Since the above statistics change at a much slower rate compared to the short-term counterpart, less frequent update is needed at the expense of power saving.

Also, ordered detection based on the symbol post-detection signal-to-interference-plus-noise ratio (SINR) is often used to reduce the effect of decision feedback error. Let the detection order be π(1), π(2), . . . , π(P) where π( ) is a permutation of the P integers {1, 2, . . . ,P}; that is, the first estimated symbol (hard estimate output) will be ŝ_{π(1)}. The maximum SINR of the components of the first soft estimate z⁽¹⁾, which estimates all P symbols, determines π(1). Similarly, the SINRs of the components of z⁽²⁾, which estimates all of the symbols except the cancelled s_{π(1)}, determines π(2), and so forth. That is, the ith iteration estimates symbol s_{π(i)}.

Further, MMSE detectors are known to be biased estimators in the sense that E[zₖ|sₖ]−sₖ≠0. However, the bias of the MMSE detectors can be removed by applying a scaling factor to the soft outputs. This scaling factor does not affect post-detection SINR, yet results in increased mean squared error compared to the regular biased MMSE estimate. While this unbiasing operation does not affect the performance of LMMSE detectors, it improves the performance of IMMSE detectors because the decision device generating decision feedback assumes unbiased soft output. The unbiasing operation for IMMSE detectors rescales the soft estimates zₖ to soft estimates \check{z}ₖ as follows:

$${\breve{z}}_{k} = {z}_{k} / {ρ}_{k} where$$

$$\begin{matrix}{ρ}_{k} = {λ}_{k} {{h}_{k}^{H} [ {A}_{k} {Λ}_{k} {A}_{k}^{H} + {σ}^{2} {I}_{Q} ]}^{- 1} {h}_{k} \\ = {( {[ {A}_{k}^{H} {A}_{k} + {σ}^{2} {Λ}_{k}^{- 1} ]}^{- 1} {A}_{k}^{H} {A}_{k} )}_{1 , 1}\end{matrix}$$

Aₖ is the Q×(P−k+1) matrix [hₖ, hₖ₊₁, . . . , h_{P}], and the subscript 1,1 denotes the (1,1) matrix element. For unbiased IMMSE, variance-based and mean-squared-error-based normalizations are equivalent.

For a channel encoder (e.g., FIG. 3b) using a convolution code, the demodulator (e.g., FIG. 3c) converts the output P soft symbol estimates, z₁, z₂, . . . , z_{P}, into (bit-level) conditional probabilities of the transmitted symbols, s₁, s₂, . . . , s_{P}; and a decoder may translate (using a channel model) the conditional probabilities into branch metric values for trellis path searching. In particular, a maximum likelihood sequential (Viterbi) decoder may use a branch metric derived from bit-level versions of log{p(z|s)}, whereas a Fano algorithm sequential decoder may use a branch metric from bit-level versions of log{p(z|s)/p(z)}−K where K equals log₂ of the number of possible inputs. For a channel encoder using a turbo code, the demodulator may provide log-likelihood ratios like log{p(b=0|z)/p(b=1|z)} to an iterative MAP decoder. Of course, a hard decision decoder just directly converts the soft symbol estimates into hard symbol estimates.

For example, an AWGN channel where the residual interference (interference which is not cancelled) is also a zero-mean, normally-distributed, independent random variable, gives:
p(zₖ|sₖ=c)˜exp(−|zₖ−c|²/γₖ)
where c is a symbol in the symbol constellation and γₖ is a scaling (normalization) typically derived from the channel characteristics and the detector type. Of course, γₖ is just twice the variance of the estimation error random variable.

For LZF type detectors the natural choice of γₚ is the variance of the noise term associated with the soft estimate; that is, γₚ=var(nₚ) where zₚ=sₚ+nₚ. This relates to the AWGN noise power of the channel (σ²) and the corresponding (p,p) diagonal term of the matrix which amplifies the channel noise:
γₚ=σ²[H^{H}H]⁻¹_{p,p}
And for the iterative ZF detector (with numerical ordering) the analog applies:
γₚ=σ²[Aₚ^{H}Aₚ]⁻¹_{1,1}
where the (1,1) element corresponds to the channel from the pth symbol source due to the definition of Aₚ with first column equal hₚ.

For MMSE-type detectors a natural choice is to take γₚ as the mean squared error:
γₚ=E[|zₚ−sₚ|²]
For LMMSE this translates to
γₚ=σ²[H^{H}H+σ²Λₚ⁻¹]⁻¹_{p,p}
and for the unordered iterative MMSE the analog obtains:
γₚ=σ²[Aₚ^{H}Aₚ+σ²Λₚ⁻¹]⁻¹_{1,1}
MMSE-type detectors can also use variance type scaling.

Because MMSE detectors are biased in the sense that the mean of the estimation error is not zero, the variance scaling becomes
γₚ=E[|zₚ−sₚ|²]−E[zₚ−sₚ]|².
For linear MMSE this is
γₚ=σ²([H^{H}H+σ²Λ⁻¹]⁻¹H^{H}H[H^{H}H+σ²Λ⁻¹]⁻¹)_{p,p}
and for unordered iterative MMSE this is:
γₚ=σ²([Aₚ^{H}Aₚ+σ²Λₚ⁻¹]⁻¹Aₚ^{H}Aₚ[Aₚ^{H}Aₚ+σ²Λ_{P}⁻¹]⁻¹)_{1,1}
The bias of the MMSE detectors can be removed as previously described, and for unbiased detectors the mean-squared-error scaling and the variance scaling are thus equivalent.

An alternative scaling simply takes
γₚ=σ²/(λₚ∥hₚ∥²) for p=1, 2, . . . , P
where ∥hₚ∥² is the square of the norm of the channel Q-vector hₚ; that is, the sum of the squared magnitudes of the Q components of the pth column of channel matrix H.

In terms of the bits bₖⱼ which define the symbol sₖ in its constellation (e.g., two bits for a QPSK symbol, four bits for a 16 QAM symbol, et cetera), take as a practical approximation P(zₖ|bₖⱼ=1)=p(zₖ|sₖ=cₖⱼ=1) where cₖⱼ₌₁ is the symbol in the sub-constellation of symbols with jth bit equal 1 and which is the closest to zₖ; that is, cₖⱼ₌₁ minimizes |zₖ−cⱼ₌₁|² for cⱼ₌₁ a symbol in the sub-constellation with jth bit equal to 1. The analog applies for p(zₖ|bₖⱼ=0) using the sub-constellation of symbols with jth bit equal 0.

Similarly, the decoder for a binary trellis may use log likelihood ratios (LLRs) which are defined as

$$\begin{matrix}LLR ( {b}_{kj} ) = log \{ P [ {b}_{kj} = 1 \vert {z}_{k} ] / P [ {b}_{kj} = 0 \vert {z}_{k} ] \} \\ = log \{ P [ {b}_{kj} = 1 \vert {z}_{k} ] \} - log \{ P [ {b}_{kj} = 0 \vert {z}_{k} ] \} \\ = log \{ p ( {z}_{k} \vert {b}_{kj} = 1 ) / p ( {z}_{k} \vert {b}_{kj} = 0 ) \} + log \{ P [ {b}_{kj} = 1 ] / P [ {b}_{kj} = 0 ] \}\end{matrix}$$

where the first log term includes the probability distribution of the demodulated symbol zₖ which can be computed using the channel model. The second log term is the log of the ratio of a priori probabilities of the bit values and typically equals 0. Then again using the approximation P(zₖ|bₖⱼ=1)=p(zₖ|sₖ=cₖⱼ₌₁) where cₖⱼ₌₁ is the symbol in the sub-constellation of symbols with jth bit equal 1 and which is the closest to zₖ together with equal a priori probabilities yields:

$$\begin{matrix}LLR ( {b}_{kj} ) = log \{ p ( {z}_{k} \vert {b}_{kj} = 1 ) / p ( {z}_{k} \vert {b}_{kj} = 0 ) \} \\ ≅ 1 / {γ}_{k} \{ {min}_{j = 0} \vert {z}_{k} - {c}_{j = 0} {\vert}^{2} - {min}_{j = 1} \vert {z}_{k} - {c}_{j = 1} {\vert}^{2} \}\end{matrix}$$

Thus the LLR computation just searches over the two symbol sub-constellations for the minima. The magnitude of LLR(bₖⱼ) indicates the reliability of the hard decision bₖⱼ=0 when LLR(bₖⱼ)<0 and bₖⱼ=1 when LLR(bₖⱼ)≧0.

The LLRs are used in decoders for error correcting codes such as Turbo codes (e.g., iterative interleaved MAP decoders with BCJR or SOVA algorithm using LLRs for each MAP) and convolutional codes (e.g. Viterbi decoders). Such decoders require soft bit statistics (in terms of LLR) from the detector to achieve their maximum performance (hard bit statistics with Hamming instead of Euclidean metrics can also be used but result in approximately 3 dB loss). Alternatively, direct symbol decoding with LLRs as the conditional probability minus the a priori probability could be used.

What is claimed is:

1. A method of detection, comprising:
(a) receiving a Q-dimensional signal representing a set of P transmitted symbols where P is a positive integer greater than 1 and Q is a positive integer at least as great as P;
(b) estimating the Q×P channel matrix for said signal;
(c) using the results of step (b) to select a detection method from a plurality of detection methods, each of said detection methods differing from others of said plurality; and
(d) applying said selected detection method of step (c) to said received signal of step (a).

2. The method of claim 1, wherein:
(a) the using of step (c) of claim 1 includes computing a metric value from the results of step (b) of claim 1 where said metric measures a transmission condition of the Q×P channel for said signal.

3. The method of claim 2, wherein:
(a) said condition of step (a) of claim 2 is selected from the group consisting of condition numbers of matrices associated with said channel matrix, statistics of the distribution of (normalized) channel correlation(s) of said Q×P channel for said signal, statistics of the distribution of expectations of the (normalized) channel correlation(s) of said Q×P channel for said signal, the foregoing with additive noise, and combinations of the foregoing.

4. The method of claim 1, further comprising:
(a) applying said selected detection method of step (c) of claim 1 to a first plurality of received signals;
(b) reestimating the Q×P channel matrix;
(c) using the results of step (b) to select a second detection method from said plurality of detection methods, where said second selected detection method may be the same as said selected detection method; and
(d) applying said second selected detection method of step (c) to a second plurality of received signals.

5. The method of claim 1, wherein:
(a) said Q-dimensional signal is received from Q antennas and said set of P transmitted symbols were transmitted from P antennas.

6. The method of claim 2, wherein:
(a) said using of step (c) of claim 1 includes comparing said metric of step (a) of claim 2 to one or more thresholds.

7. The method of claim 1, wherein:
(a) said plurality of detection methods includes maximum likelihood detection and iterative linear minimum mean squared error detection.

8. The method of claim 1, wherein:
(a) said plurality of detection methods includes maximum likelihood detection and iterative linear zero forcing detection.

9. A method of MIMO detection, comprising:
(a) receiving a first sequence of N Q-vector signals from transmission of a sequence of N P-vectors where N is a positive integer, P is a positive integer greater than 1, and Q is a positive integer at least as great as P;
(b) estimating the Q×P channel matrix for said transmission;
(c) using the results of step (b) to select a first detection method from a plurality of detection methods, each of said detection methods differing from others of said plurality;
(d) applying said first selected detection method of step (c) to said first sequence of signals of step (a); and
(e) repeating foregoing steps (a)-(d) for a second sequence of N Q-vector signals.

10. The method of claim 9, wherein:
(a) N=1; and
(b) the using of step (c) of claim 9 includes (i) computing a metric value from the results of step (b) of claim 9 where said metric measures a transmission condition of the Q×P channel for said first sequence; and (ii) comparing said metric value to one or more thresholds.

11. The method of claim 10, wherein:
(a) the transmission condition of step (b) of claim 10 is selected from the group consisting of condition numbers of matrices associated with said channel matrix, statistics of the distribution of (normalized) channel correlation(s) of said Q×P channel for said signal, the foregoing with additive noise, and combinations of the foregoing.

12. The method of claim 9, wherein:
(a) N is greater than 1; and
(b) the using of step (c) of claim 9 includes (i) computing a metric value from the results of step (b) of claim 9 where said metric measures a transmission condition of the Q×P channel for said first sequence; and (ii) comparing said metric value to one or more thresholds.

13. The method of claim 12, wherein:
(a) the transmission condition of step (b) of claim 12 is selected from the group consisting of expectations of condition numbers of matrices associated with said channel matrix, statistics of the distribution of expectations of the (normalized) channel correlation(s) of said Q×P channel for said signal, the foregoing with additive noise, and combinations of the foregoing.

14. A signal detector, comprising:
(a) a signal input for receiving a Q-dimensional signal representing a set of P transmitted symbols where P is a positive integer greater than 1 and Q is a positive integer at least as great as P;
(b) a channel estimator coupled to said signal input, said channel estimator operable to estimate the Q×P channel for said signal;
(c) a plurality of detectors, each of said detectors with detection method differing from others of said plurality; and
(d) a selector coupling said plurality of detectors to said signal input, said selector with a control input from said channel estimator, and wherein said selector connects a single one of said plurality of detectors to said input in response to an estimate of the Q×P channel.

15. The signal detector of claim 14, wherein:
(a) said signal input is coupled to Q antennas.

16. The signal detector of claim 14, wherein:
(a) said selector operable to (i) compute a metric value from the estimate of the Q×P channel where said metric measures a transmission condition of the Q×P channel and (ii) compare the metric value to one or more thresholds.
